(19) United States
(12) Patent Application Publication
(10) Pub. No.: US 2016/0284746 A1
(43) Pub. Date: Sep. 29, 2016

(54) SOLID-STATE IMAGING DEVICE AND METHOD FOR MANUFACTURING THE SAME

(71) Applicant: KABUSHIKI KAISHA TOSHIBA, Tokyo (JP)

(72) Inventors: Kazuya FUKASE, Oita Oita (JP); Tatsuya OHGURO, Yokohama Kanagawa (JP); Hisayo MOMOSE, Yokohama Kanagawa (JP); Tetsu MOROOKA, Yokohama Kanagawa (JP); Takahisa KANEMURA, Yokohama Kanagawa (JP)

(73) Assignee: KABUSHIKI KAISHA TOSHIBA, Tokyo (JP)

(21) Appl. No.: 14/744,769

(22) Filed: Jun. 19, 2015

(30) Foreign Application Priority Data
Mar. 27, 2015 (JP) 2015-066967

(51) Int. Cl. H01L 27/146

(52) U.S. Cl. CPC H01L 27/1463; H01L 27/14643; H01L 27/14689; H01L 27/14687

(57) ABSTRACT

According to one embodiment, a solid-state imaging device includes a plurality of photoelectric conversion elements, a field effect transistor, a trench, and a P-type impurity diffusion region. The plurality of photoelectric conversion elements is two-dimensionally arranged in a semiconductor layer. The field effect transistor includes N-type source and drain on a surface side of the semiconductor layer. The trench penetrates through a surface and a rear surface of the semiconductor layer and surrounds each of the photoelectric conversion elements. The width of the trench is enlarged from the surface of the semiconductor layer toward a position at a predetermined depth, and is not enlarged at a position deeper than the position at the predetermined depth. The P-type impurity diffusion region is arranged in a side surface of the trench. A P-type impurity concentration in a portion from the surface of the semiconductor layer to the position at the predetermined depth is lower than that in a portion deeper than the position at the predetermined depth.

### CROSS-REFERENCE TO RELATED APPLICATIONS

This application is based upon and claims the benefit of priority from Japanese Patent Application No. 2015-066967, filed on Mar. 27, 2015; the entire contents of which are incorporated herein by reference.

### FIELD

Embodiments described herein generally relate to a solid-state imaging device and a method for manufacturing the same.

### BACKGROUND

In the related art, a solid-state imaging device includes a plurality of photoelectric conversion elements two-dimensionally arranged in a semiconductor layer. The photoelectric conversion elements are isolated from each other. Front deep trench isolation (FDTI) is a technology for isolating the photoelectric conversion elements from each other.

In the FDTI, the photoelectric conversion elements are isolated from each other by burying, for example, an insulating member in a relatively deep trench. The trench is arranged from a surface side to a rear surface side of a semiconductor layer in which the photoelectric conversion elements are provided, and surrounds the photoelectric conversion elements.

As a solid-state imaging device including the FDTI, there is a back side illumination type solid-state imaging device including photoelectric conversion elements formed by PN junction between a P-type impurity diffusion layer arranged in a side surface of a trench of the FDTI and an N-type semiconductor region arranged on a rear surface side of the semiconductor layer.

In the solid-state imaging device, positive holes in the P-type impurity diffusion region arranged in the side surface of the trench can capture free electrons generated due to rough surfaces of the trench. Therefore, a dark current can be suppressed.

Here, the solid-state imaging device has a larger effect of suppressing the dark current as an impurity concentration in the P-type impurity diffusion region is higher. However, in the back side illumination type solid-state imaging device, when the impurity concentration in the P-type impurity diffusion region is high, junction leakage occurs in a pixel transistor arranged on a surface layer of the semiconductor layer. Therefore, the P-type impurity diffusion region preferably has a relatively high P-type impurity concentration on the rear surface side of the semiconductor layer, and a relatively low P-type impurity concentration on the surface side.

However, in order to make the P-type impurity concentration on the surface side of the semiconductor layer lower than the P-type impurity concentration on the rear surface side, for example, it is necessary to implant ions of the N-type impurity into a shallow portion in a side wall of the trench after implanting ions of the P-type impurity into the entire side surface of the trench. In this way, when the number of a process of the ion implantation is plural, processes for manufacturing the solid-state imaging device are complicated.

### BRIEF DESCRIPTION OF THE DRAWINGS

FIG. 1 is a block diagram illustrating a schematic structure of a digital camera 1 including a solid-state imaging device according to a first embodiment;

FIG. 2 is a block diagram illustrating a schematic structure of the solid-state imaging device according to the first embodiment;

FIG. 3 is a view illustrating a schematic cross section of a pixel array according to the first embodiment;

FIG. 4 is a view illustrating a trench of FDTI according to the first embodiment;

FIG. 5 is a diagram illustrating a simulation result of the trench for the FDTI according to the first embodiment;

FIG. 6 is a diagram illustrating the simulation result of the trench for the FDTI according to the first embodiment;

FIGS. 7A to 7D are cross sectional views illustrating a process for manufacturing the pixel array according to the first embodiment;

FIGS. 8A to 8D are cross sectional views illustrating the process for manufacturing the pixel array according to the first embodiment;

FIGS. 9A to 9C are cross sectional views illustrating the process for manufacturing the pixel array according to the first embodiment;

FIG. 10 is a view illustrating a schematic cross section of a pixel array according to a second embodiment;

FIGS. 11A to 11D are cross sectional views illustrating a process for manufacturing the pixel array according to the second embodiment;

FIG. 12 is a view illustrating a schematic cross section of a pixel array according to a third embodiment; and

FIGS. 13A and 13B are cross sectional views illustrating a process for manufacturing the pixel array according to the third embodiment.

### DETAILED DESCRIPTION

A solid-state imaging device according to an embodiment includes a plurality of photoelectric conversion elements, a field effect transistor, a trench, and a P-type impurity diffusion region. The plurality of photoelectric conversion elements are two-dimensionally arranged in a semiconductor layer. The field effect transistor includes N-type source and drain on a surface side of the semiconductor layer. The trench penetrates through a surface and a rear surface of the semiconductor layer and surrounds each of the photoelectric conversion elements. The width of the trench is enlarged from the surface of the semiconductor layer toward a position at a predetermined depth, and is not enlarged at a position deeper than the position at the predetermined depth. The P-type impurity diffusion region is arranged in a side surface of the trench. P-type impurity concentration in a portion from the surface of the semiconductor layer to the position at the predetermined depth is lower than that in a portion deeper than the position at the predetermined depth.

Exemplary embodiments of a solid-state imaging device and a method for manufacturing the same will be explained below in detail with reference to the accompanying drawings. The present invention is not limited to the following embodiments.

### First Embodiment

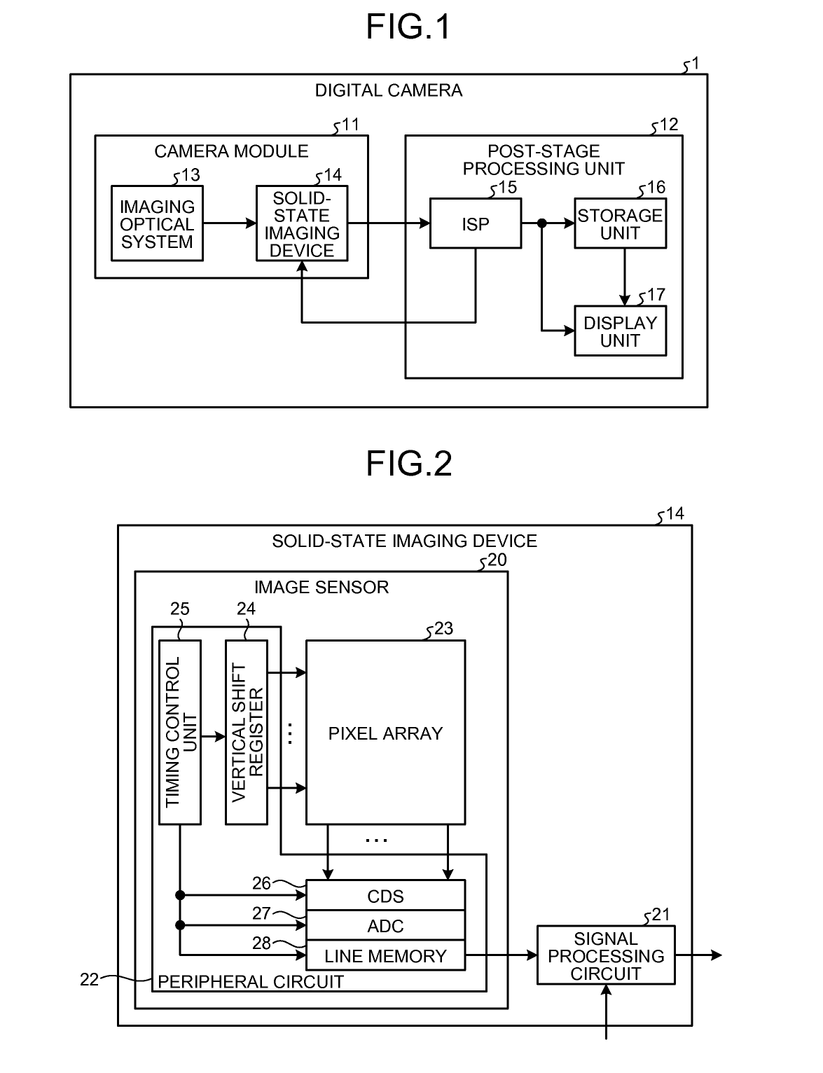

FIG. 1 is a block diagram illustrating a schematic structure of a digital camera 1 including a solid-state imaging device 14 according to a first embodiment. As illustrated in FIG. 1, the digital camera 1 includes a camera module 11 and a post-stage processing unit 12.

The camera module 11 includes an imaging optical system 13 and the solid-state imaging device 14. The imaging optical system 13 acquires light from an object and forms an object image. The solid-state imaging device 14 images the object image formed by the imaging optical system 13, and outputs an image signal obtained by imaging to the post-stage processing unit 12. The camera module 11 is applied to an electronic apparatus such as a mobile terminal with a camera, in addition to the digital camera 1.

The post-stage processing unit 12 includes an image signal processor (ISP) 15, a storage unit 16, and a display unit 17. The ISP 15 performs signal processing of an image signal input from the solid-state imaging device 14. The ISP 15 performs image quality enhancement processing such as noise removing processing, defective pixel correcting processing, and resolution conversion processing.

The ISP 15 outputs the image signal after the signal processing to the storage unit 16, the display unit 17, and a signal processing circuit 21 described later, included in the solid-state imaging device 14 in the camera module 11 (refer to FIG. 2). The image signal fed back from the ISP 15 to the camera module 11 is used to adjust or control the solid-state imaging device 14.

The storage unit 16 stores the image signal input from the ISP 15 as an image. In addition, the storage unit 16 outputs the image signal of the stored image to the display unit 17 in accordance with operation by a user or the like. The display unit 17 displays an image in accordance with the image signal input from the ISP 15 or the storage unit 16. The display unit 17 is, for example, a liquid crystal display.

Next, the solid-state imaging device 14 included in the camera module 11 will be described with reference to FIG. 2. FIG. 2 is a block diagram illustrating a schematic structure of the solid-state imaging device 14 according to the first embodiment. As illustrated in FIG. 2, the solid-state imaging device 14 includes an image sensor 20 and the signal processing circuit 21.

Here, a case where the image sensor 20 is a so-called back side illumination type complementary metal oxide semiconductor (CMOS) image sensor will be described. In the back side illumination type CMOS image sensor, a wiring layer is formed on an opposite side to a light receiving surface of the photoelectric conversion elements photoelectrically converting incident light.

The image sensor 20 includes a peripheral circuit 22 mainly including an analog circuit, and a pixel array 23. The peripheral circuit 22 includes a vertical shift register 24, a timing control unit 25, a correlation double sampling unit (CDS) 26, an analog digital conversion unit (ADC) 27, and a line memory 28.

The pixel array 23 is arranged in an imaging region of the image sensor 20. In the pixel array 23, a plurality of photoelectric conversion elements corresponding to respective pixels of the imaged image are arranged in a two-dimensional array form (matrix form) in a horizontal direction (row direction) and in a vertical direction (column direction).

The plurality of photoelectric conversion elements are isolated from each other by front deep trench isolation (FDTI) extending from the surface to the rear surface of a semiconductor layer in which the photoelectric conversion elements are arranged in a depth direction of the semiconductor layer.

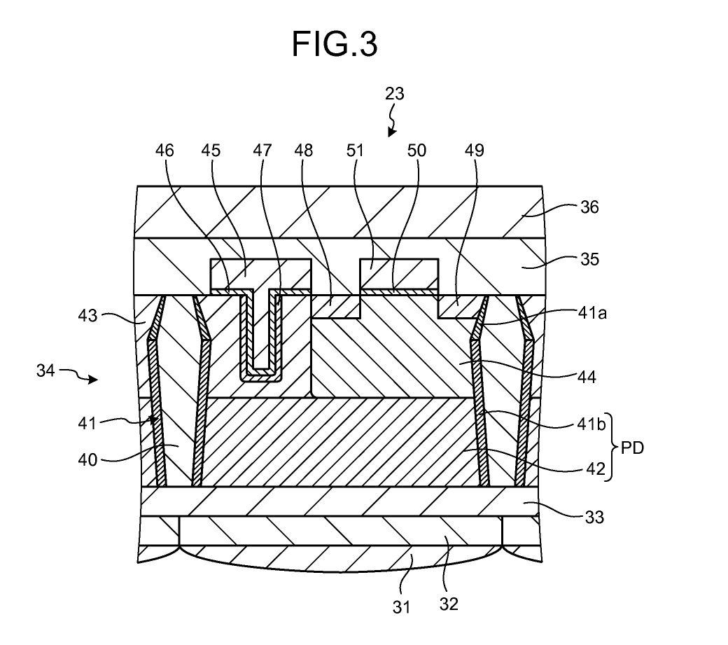

In the FDTI of the present embodiment, the width of the trench is enlarged from the surface of the semiconductor layer toward a position at a predetermined depth, and is not enlarged from the position at the predetermined depth toward the rear surface of the semiconductor layer. Specifically, the width of the trench is approximately constant or reduced in a tapered shape toward the rear surface of the semiconductor layer. A manufacturing process can be thereby simplified. Details of the pixel array 23 including the FDTI will be described later with reference to FIG. 3.

The timing control unit 25 is connected to the vertical shift register 24, the CDS 26, the ADC 27, and the line memory 28 to control operation timing of the vertical shift register 24, the CDS 26, the ADC 27, and the line memory 28.

The vertical shift register 24 is a processing unit which outputs, to the pixel array 23, a selection signal to sequentially select, in row units, photoelectric conversion elements reading a signal charge from the plurality of photoelectric conversion elements arranged in a two-dimensional array (row/column) form.

The pixel array 23 outputs, from the photoelectric conversion elements to the CDS 26, the signal charges accumulated in the photoelectric conversion elements selected in row units by the selection signal input from the vertical shift register 24, as a pixel signal indicating luminance of each pixel.

The CDS 26 is a processing unit which removes a noise from the pixel signal input from the pixel array 23 by correlation double sampling to output the pixel signal to the ADC 27. The ADC 27 is a processing unit which converts the analog pixel signal input from the CDS 26 into a digital pixel signal to output the pixel signal to the line memory 28. The line memory 28 is a processing unit which temporarily holds the pixel signal input from the ADC 27 to output the pixel signal to the signal processing circuit 21 in each row of the photoelectric conversion elements in the pixel array 23.

The signal processing circuit 21 is a processing unit which mainly includes a digital circuit, and performs predetermined signal processing for the pixel signal input from the line memory 28 to output the pixel signal after the signal processing to the post-stage processing unit 12 as an image signal. The signal processing circuit 21 performs signal processing such as lens shading correction, defect correction, and noise reduction processing for the pixel signal.

In this way, in the image sensor 20, the plurality of photoelectric conversion elements arranged in the pixel array 23 photoelectrically convert incident light into signal charges in an amount corresponding to an amount of received light to accumulate the signal charges. The peripheral circuit 22 reads the signal charges accumulated in the photoelectric conversion elements as a pixel signal. Imaging is thereby performed.

Next, a cross sectional structure of the pixel array 23 according to the first embodiment will be described with reference to FIG. 3. FIG. 3 is a view illustrating a schematic cross section of the pixel array 23 according to the first embodiment. FIG. 3 illustrates a schematic cross section of a part corresponding to one pixel of the imaged image in the pixel array 23.

As illustrated in FIG. 3, the pixel array 23 includes a microlens 31, a color filter 32, an antireflection film 33, a semiconductor layer 34, an insulating layer 35, and a supporting substrate 36, stacked in order from a side on which light is incident (here, a lower side).

The microlens 31 is a plano-convex lens which collects incident light into photoelectric conversion elements PD arranged in the semiconductor layer 34. The color filter 32 selectively transmits light of any one color of incident red, green, and blue light. The antireflection film 33 is formed, for example, of silicon nitride, and prevents the incident light from reflecting.

The semiconductor layer 34 is, for example, an epitaxial layer of silicon. FDTI 41 is arranged in the semiconductor layer 34. The FDTI 41 includes an insulating portion 40 formed of an insulating material such as silicon oxide, in the trench penetrating through the surface and the rear surface of the semiconductor layer 34 and dividing the semiconductor layer 34 into plane-view lattice shaped parts.

In the FDTI 41 of the present embodiment, the width of the trench is enlarged from the surface of the semiconductor layer 34 toward a position at a predetermined depth, and is not enlarged at a position deeper than the position at the predetermined depth.

Specifically, the width of the trench is reduced in a linearly tapered shape from the position at the predetermined depth of the semiconductor layer 34 toward the surface of the semiconductor layer 34. The width of the trench is approximately constant or reduced in a linearly tapered shape from the position at the predetermined depth of the semiconductor layer 34 toward the rear surface of the semiconductor layer 34.

In a side surface of the FDTI 41, a P-type impurity diffusion region which is doped with a P-type impurity such as boron is arranged. Specifically, in the semiconductor layer 34, the P-type impurity diffusion region having a relatively low P-type impurity concentration (hereinafter, referred to as “low concentration P-type region 41a”) is arranged in a portion from the surface of the semiconductor layer 34 up to a position at a predetermined depth in the side surface of the FDTI 41.

On the other hand, in the semiconductor layer 34, the P-type impurity diffusion region having a relatively high P-type impurity concentration (hereinafter, referred to as “high concentration P-type region 41b”) is arranged in a portion other than the low concentration P-type region 41a in the side surface of the FDTI 41.

In addition, the semiconductor layer 34 includes the photoelectric conversion elements PD on the rear surface side. The photoelectric conversion elements PD are arranged on the rear surface side of the semiconductor layer 34. The photoelectric conversion elements PD form a photodiode by PN junction between an N-type semiconductor region 42 and the high concentration P-type region 41b. The N-type semiconductor region 42 is doped with an N-type impurity such as phosphorus in a relatively high concentration.

In addition, the semiconductor layer 34 includes a silicon epitaxial layer 43 arranged on a surface layer side thereof and a P-type well 44 arranged in the epitaxial layer 43. The epitaxial layer 43 is doped with a P-type impurity in a relatively low concentration. A buried gate 45 of a transfer transistor is buried in the epitaxial layer 43.

A gate insulating film 46 is arranged between the buried gate 45 and the epitaxial layer 43. In the side surface of the trench in which the buried gate 45 in the epitaxial layer 43 is buried, a P-type semiconductor region 47 which is doped with a P-type impurity such as boron is arranged.

On a surface layer of the P-type well 44, a floating diffusion 48 as a source of a reset transistor and a drain 49 of the reset transistor are arranged. The floating diffusion 48 and the drain 49 are regions which are doped with an N-type impurity such as phosphorus in a relatively high concentration.

On the surface of the P-type well 44 between the floating diffusion 48 and the drain 49 of the reset transistor, a reset gate 51 is arranged with a gate insulating film 50 therebetween. The reset gate 51 and an upper portion of the buried gate 45 are arranged in the insulating layer 35.

In the pixel array 23, the photoelectric conversion elements PD photoelectrically convert incident light from the microlens 31 into signal charges corresponding to an amount of received light to accumulate the signal charges in the N-type semiconductor region 42. Thereafter, the pixel array 23 transfers the signal charges from the N-type semiconductor region 42 to the floating diffusion 48 when a predetermined voltage is applied to the buried gate 45.

The pixel array 23 amplifies a voltage corresponding to the signal charges held in the floating diffusion 48 to output the signal charges to the peripheral circuit 22 (refer to FIG. 2) as a pixel signal. In addition, the pixel array 23 discharges the signal charges held in the floating diffusion 48 to the drain 49 to reset a potential of the floating diffusion 48 to a reference potential when a predetermined voltage is applied to the reset gate 51.

Here, in the pixel array 23, when a trench for the FDTI 41 is formed, a crystal defect may occur on a side surface of the trench and free electrons may be generated. However, the free electrons are captured by the high concentration P-type region 41b arranged in the side surface of the trench near the photoelectric conversion elements PD.

A predetermined depth of the trench for the FDTI 41 of the present embodiment is set, for example, to be smaller than that of the position of the N-type semiconductor region 42 in which PN junction of the photoelectric conversion elements PD is formed. The pixel array 23 can thereby suppress generation of a dark current caused by the crystal defect on the side surface of the trench.

In addition, in the pixel array 23, the drain 49 of the reset transistor is close to the P-type impurity diffusion region arranged in the side surface of the trench for the FDTI 41. The predetermined depth of the trench for the FDTI 41 of the present embodiment is set, for example, to be larger than that of the source of the reset transistor or the drain 49. As a result, the P-type impurity diffusion region close to the drain 49 of the reset transistor is the low concentration P-type region 41a, and therefore, junction leakage can be suppressed.

In this way, when the low concentration P-type region 41a is formed in an upper portion and the high concentration P-type region 41b is formed in a lower portion, along the side surface of the trench for the FDTI 41, it is generally necessary to implant ions plural times into each side surface.

For example, first, in the first ion implantation, the P-type impurity is implanted into the entire side surface of the trench from an oblique direction in a relatively high concentration to form the high concentration P-type region 41b on the entire side surface of the trench. Thereafter, in the second ion implantation, the N-type impurity is implanted into an upper portion of the trench from an oblique direction to form the low concentration P-type region 41a in the upper portion of the trench.

In this way, the low concentration P-type region 41a can be formed in the upper portion and the high concentration P-type region 41b can be formed in the lower portion, along the side surface of the trench. However, when the ions are implanted plural times, a manufacturing process is undesirably complicated.

Furthermore, as described above, in the FDTI, the semiconductor layer 34 is divided into plane-view lattice shaped parts. Therefore, when the ions of the N-type impurity are implanted into the trench formed in the lattice shape from an oblique direction, the impurity is implanted into a deeper position of the trench at an intersection of the trench than in parts other than the intersection.

Specifically, the width of the trench is larger at the intersection than in parts other than the intersection, and therefore, a frontage for the ion implantation is wider. The impurity is implanted into a deeper position of the trench at the intersection of the trench than in parts other than the intersection. In this way, when the ions of the N-type impurity are implanted into a deep position of the trench, the P-type impurity concentration is decreased even in the vicinity of the photoelectric conversion elements PD, and an effect of suppressing the dark current is reduced.

Therefore, in the present embodiment, the trench for the FDTI 41 has a reversed tapered shape from the surface of the semiconductor layer 34 to a position at a predetermined depth, and has an approximately vertical or normal tapered shape at a position deeper than the position at the predetermined depth. As a result, the number of the ion implantation is reduced, and the depth of the low concentration P-type region 41a is uniform.

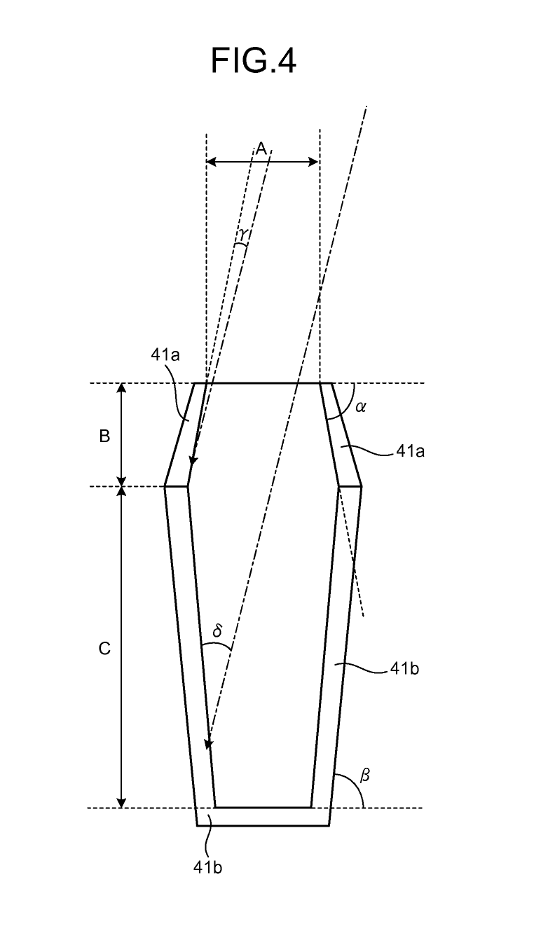

Next, a shape of the trench for the FDTI 41 and an effect caused by the shape will be described with reference to FIG. 4. FIG. 4 is a view illustrating the trench for the FDTI 41 according to the first embodiment. Note that the trench part for the FDTI 41 formed in the semiconductor layer 34 is enlarged in FIG. 4.

As illustrated in FIG. 4, the width of the trench of the present embodiment is enlarged in a linearly tapered shape from an upper surface of the trench toward a position at a predetermined depth (here, the position at a depth B). In addition, the width of the trench is approximately constant or reduced in a linearly tapered shape from the position at the predetermined depth (here, the position at the depth B) toward a position at a depth of the bottom surface of the trench (here, the position at a depth B+C).

When the ions of the P-type impurity are implanted into the side surface of the trench from an upper oblique direction, as illustrated by an alternate long and short dash line arrow in FIG. 4, the ions of the impurity are implanted into the side surface of a portion shallower than the depth B at an angle γ. On the other hand, the ions of the impurity are implanted into the side surface of a portion deeper than the depth B at an angle 5 larger than the angle γ.

Therefore, the ions of the P-type impurity are implanted into the side surface of the portion shallower than the depth B in an amount less than into the side surface of the portion deeper than the depth B. As a result, according to the trench of the present embodiment, by implanting ions once, the low concentration P-type region 41a can be formed in the side surface of the portion shallower than the depth B, and simultaneously, the high concentration P-type region 41b can be formed in the side surface of the portion deeper than the depth B.

Therefore, according to the present embodiment, by reducing the number of the ion implantation required for forming the low concentration P-type region 41a and the high concentration P-type region 41b, a process for manufacturing the solid-state imaging device 14 can be simplified.

Here, the P-type impurity concentration in each of the low concentration P-type region 41a and the high concentration P-type region 41b is determined by a size of the trench, a tapered angle thereof, and a tilt angle of an ion beam with which the trench is irradiated.

The tapered angle of the trench and the tilt angle of the ion beam were changed in the structure of the trench having the shape illustrated in FIG. 4, and simulation was performed to examine whether the P-type impurity concentration in each of the low concentration P-type region 41a and the high concentration P-type region 41b becomes a desired concentration. A result thereof will be described.

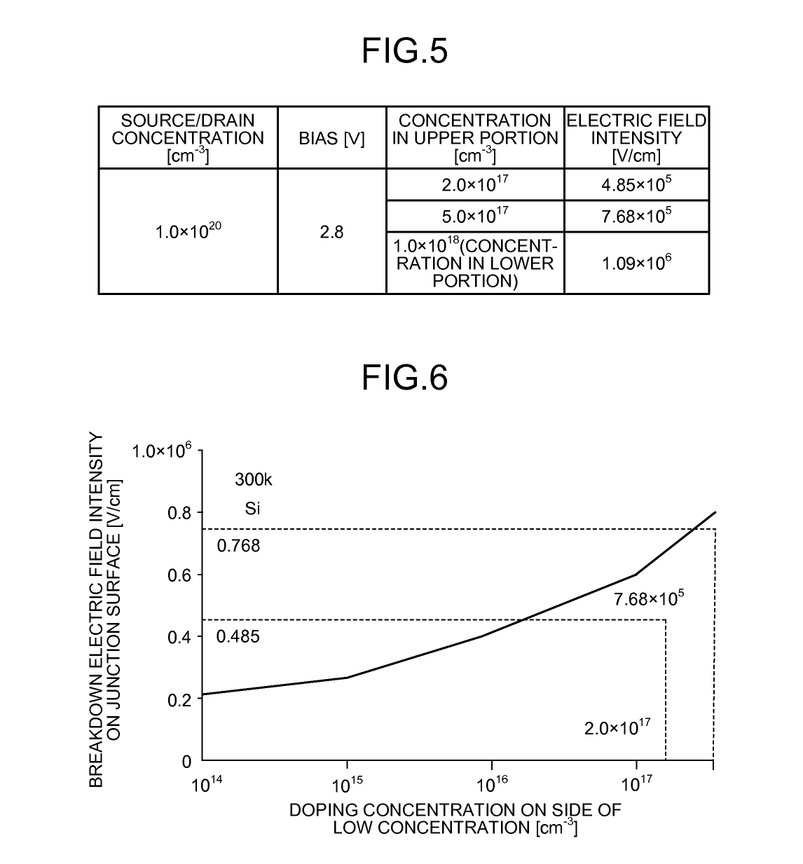

FIGS. 5 and 6 are diagrams illustrating a simulation result of the trench for the FDTI 41 according to the first embodiment. In the simulation, by using a trench having an upper surface width of 0.16 μm, a depth of 1.5 μm, a reversed tapered shape from the upper surface to the depth 0.2 μm, and a normal tapered shape from the depth 0.2 μm to 1.5 μm, the tapered angle of the trench and the tilt angle of the ion beam were changed.

Specifically, the tilt angle of the ion beam with respect to the depth direction of the trench was changed in a range of 5° to 7°. In addition, a tapered angle α between the upper surface of the trench and the reversed tapered portion in an upper part of the trench was changed in a range of 83.7° to 85.7°. A tapered angle β between the bottom surface of the trench and the normal tapered portion in a lower part thereof was changed in a range of 88° to 90°.

As a result, the P-type impurity concentration in the low concentration P-type region 41a in the upper part of the trench was 0.21 to 0.50 times the P-type impurity concentration in the high concentration P-type region 41b in the lower part of the trench. Here, when the P-type impurity concentration is 1E17 [atoms/cm³] or more in the low concentration P-type region 41a in the upper part of the trench, the dark current is reduced.

When the P-type impurity concentration in the high concentration P-type region 41b in the lower part of the trench is 1E18 [atoms/cm3], which is preferable as a value for the P-type region of the photodiode, in the trench having the above-described size, the P-type impurity concentration in the low concentration P-type region 41a in the upper part of the trench is 2E17 [atoms/cm³] to 5E17 [atoms/cm³].

In the range of the P-type impurity concentration in the low concentration P-type region 41a in the upper part of the trench, pressure resistance was verified under conditions illustrated in FIG. 5 in a junction surface between the source of the reset transistor and the low concentration P-type region 41a in the upper part of the trench or between the drain 49 and the low concentration P-type region 41a in the upper part of the trench.

Here, the N-type impurity concentration of each of the source of the reset transistor (floating diffusion 48) and the drain 49 was assumed to be 1E20 [atoms/cm³]. The source or the drain of the reset transistor was joined to the low concentration P-type region 41a in the upper part of the trench, and a bias of 2.8 [V] as a power supply voltage was applied.

As a result, as illustrated in FIG. 5, when the P-type impurity concentration in the low concentration P-type region 41a in the upper part of the trench was 2E17 [atoms/cm³], an electric field intensity was 4.85E5 [V/cm]. When the P-type impurity concentration in the low concentration P-type region 41a in the upper part of the trench was 5E17 [atoms/cm³], an electric field intensity was 7.68E5 [V/cm].

This result is applied to a graph illustrating a relation between a doping concentration on a side of the low concentration and a breakdown electric field intensity on the junction surface, illustrated in FIG. 6. Then, when the P-type impurity concentration in the low concentration P-type region 41a in the upper part of the trench is 2E17 [atoms/cm³], the electric field intensity does not exceed the breakdown electric field intensity.

When the P-type impurity concentration in the low concentration P-type region 41a in the upper part of the trench is 5E17 [atoms/cm³], the electric field intensity does not exceed the breakdown electric field intensity, either. This indicates that junction leakage does not occur in the reset transistor having the structure of the trench illustrated in FIG. 4. In other words, according to the structure of the trench illustrated in FIG. 4, the P-type impurity concentration in each of the low concentration P-type region 41a and the high concentration P-type region 41b can be a desired concentration.

The above-described simulation indicates that the tapered angle β between the bottom surface of the trench and the normal tapered portion in the lower part thereof may be 90°. That is, it is indicated that a portion deeper than the position at the predetermined depth with respect to the upper surface of the trench does not necessarily have a normal tapered shape, and may have a uniform width regardless of the depth unless having a reversed tapered shape.

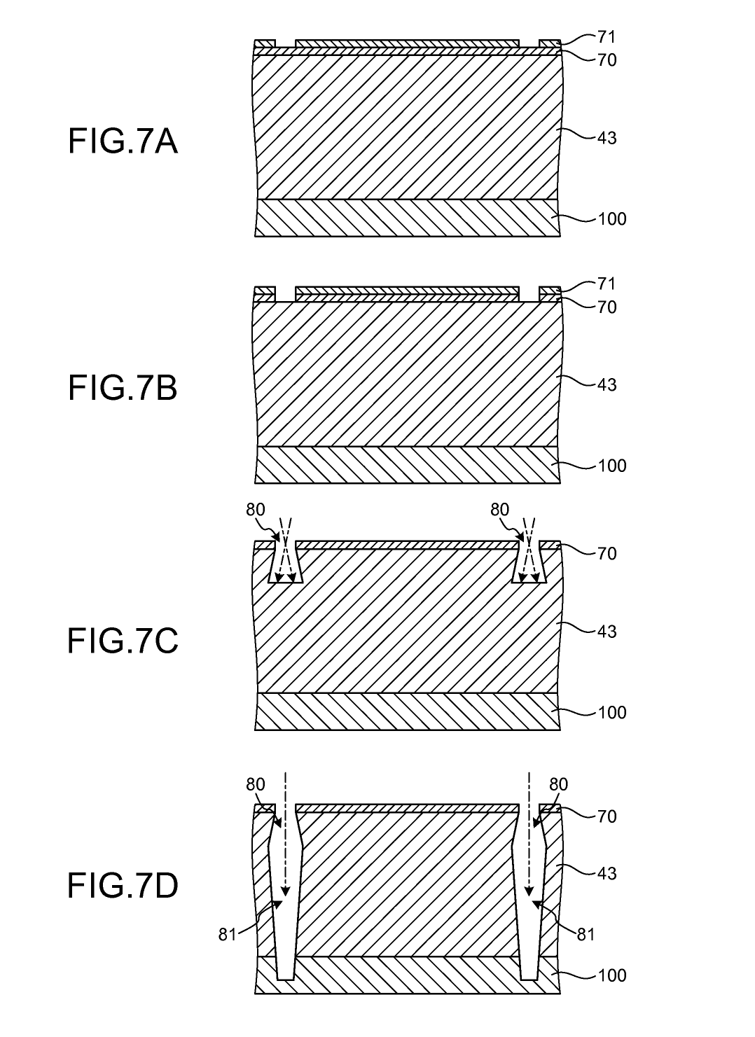

Next, a method for manufacturing the pixel array 23 according to the first embodiment will be described with reference to FIGS. 7A to 9C. FIGS. 7A to 9C are cross sectional views illustrating a process for manufacturing the pixel array 23 according to the first embodiment. Here, a process for manufacturing the portion illustrated in FIG. 3, of the pixel array 23 will be described.

When the pixel array 23 is manufactured, first, as illustrated in FIG. 7A, a substrate is prepared. In the substrate, the silicon epitaxial layer 43 which is doped with a P-type impurity such as boron in a relatively low concentration is formed on a semiconductor substrate 100 such as silicon wafer.

A hard mask 70 is formed on the surface of the epitaxial layer 43, for example, with silicon nitride, and a resist 71 is deposited on the hard mask 70. Thereafter, by patterning the resist 71 by photolithography, the resist 71 at a position for forming the FDTI 41 is selectively removed to perform reactive ion etching (RIE) using the resist 71 as a mask.

Then, as illustrated in FIG. 7B, the hard mask 70 in a position where the resist 71 is removed is selectively removed to perform patterning of the hard mask 70. Subsequently, as illustrated in FIG. 7C, the resist 71 is removed, and then RIE is performed using the hard mask 70 as a mask to thereby form the trench for the FDTI 41.

Here, first, a first trench 80 is formed from the surface of the epitaxial layer 43 as a semiconductor layer up to a position at a predetermined depth. At this time, anisotropic etching is performed to the position for forming the first trench 80 on the surface of the epitaxial layer 43 in an oblique direction. The first trench 80 is formed so as to have an enlarged width from the surface of the epitaxial layer 43 toward the position at the predetermined depth.

More specifically, for example, anisotropic RIE is performed four times in total while the substrate is inclined in the front, rear, left, and right directions to thereby form the first trench 80. The first trench 80 has a width reduced in a linearly tapered shape from the position at the predetermined depth in the epitaxial layer 43 toward the surface of the epitaxial layer 43.

The method for forming the first trench 80 is not limited to this method. For example, when mixed gas of hydrogen fluoride, oxygen, or the like is used as etching gas, the first trench 80 having the shape illustrated in FIG. 7C may be formed by adjusting a mixing ratio of the etching gas, a flow rate thereof, acceleration voltage, or the like.

Thereafter, anisotropic etching is performed to the bottom surface of the first trench 80 in a depth direction of the epitaxial layer 43 to thereby form a second trench 81. The second trench 81 has a width not enlarged at a position deeper than the position at the predetermined depth in the epitaxial layer 43.

In FIG. 7D, the second trench 81 has a width reduced in a linearly tapered shape from the position at the predetermined depth in the epitaxial layer 43 toward the rear surface of the epitaxial layer 43, However, the width of the second trench 81 may be uniform regardless of the depth.

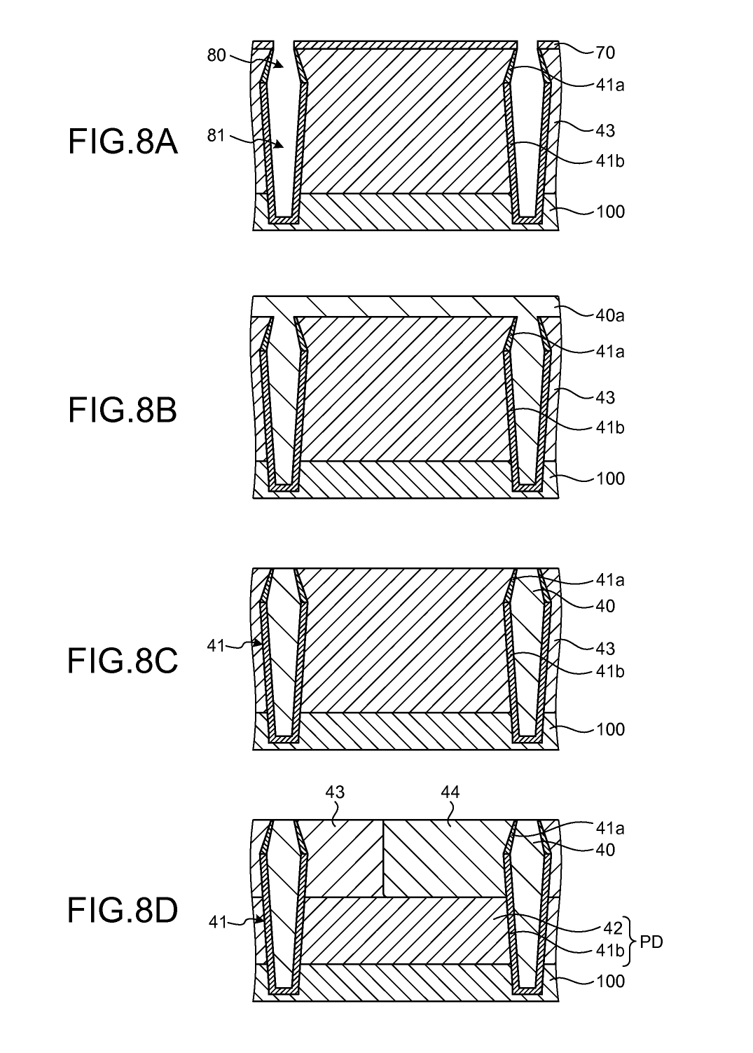

Thereafter, ions of a P-type impurity such as boron are implanted into the first trench 80 and the second trench 81 from an oblique direction. Here, as illustrated in FIG. 8A, the first trench 80 has a width reduced in a tapered shape toward the surface of the epitaxial layer 43. The second trench 81 has a width reduced in a tapered shape toward the rear surface of the epitaxial layer 43.

Therefore, an incident angle of the P-type impurity with respect to the side surface of the first trench 80 is smaller than the incident angle of the P-type impurity with respect to the side surface of the second trench 81. A concentration of the P-type impurity ions of which are implanted into the side surface of the first trench 80 is thereby lower than that of the P-type impurity ions of which are implanted into the side surface of the second trench 81.

Therefore, by performing an annealing treatment after the ions are implanted once as described above, the low concentration P-type region 41a in the side surface of the first trench 80 and the high concentration P-type region 41b in the side surface of the second trench 81 can be formed simultaneously.

In this way, in the present embodiment, by implanting the ions once into one side surface of the trench, the low concentration P-type region 41a and the high concentration P-type region 41b can be formed simultaneously. Therefore, a process for manufacturing the pixel array 23 can be more simplified than in a case where ion implantation is performed plural times into one side surface of the trench.

Subsequently, as illustrated in FIG. 8B, the hard mask 70 is removed, and then a silicon oxide layer 40a is stacked on the surface of the epitaxial layer 43, for example, by chemical vapor deposition (CVD). Thereafter, as illustrated in FIG. 8C, the unnecessary silicon oxide layer 40a is removed from the surface of the epitaxial layer 43. The insulating portion 40 in which the first trench 80 and the second trench 81 are filled with silicon oxide is thereby formed.

Subsequently, as illustrated in FIG. 8D, ions of an N-type impurity such as phosphorus are implanted into the rear surface side of the epitaxial layer 43, and the annealing treatment is performed. The N-type semiconductor region 42 is thereby formed. The photoelectric conversion elements PD are thereby formed by PN junction between the N-type semiconductor region 42 and the high concentration P-type region 41b.

Furthermore, ions of a P-type impurity such as boron are implanted into a position for forming the reset transistor on the surface layer of the epitaxial layer 43, and the annealing treatment is performed. The P-type well 44 is thereby formed.

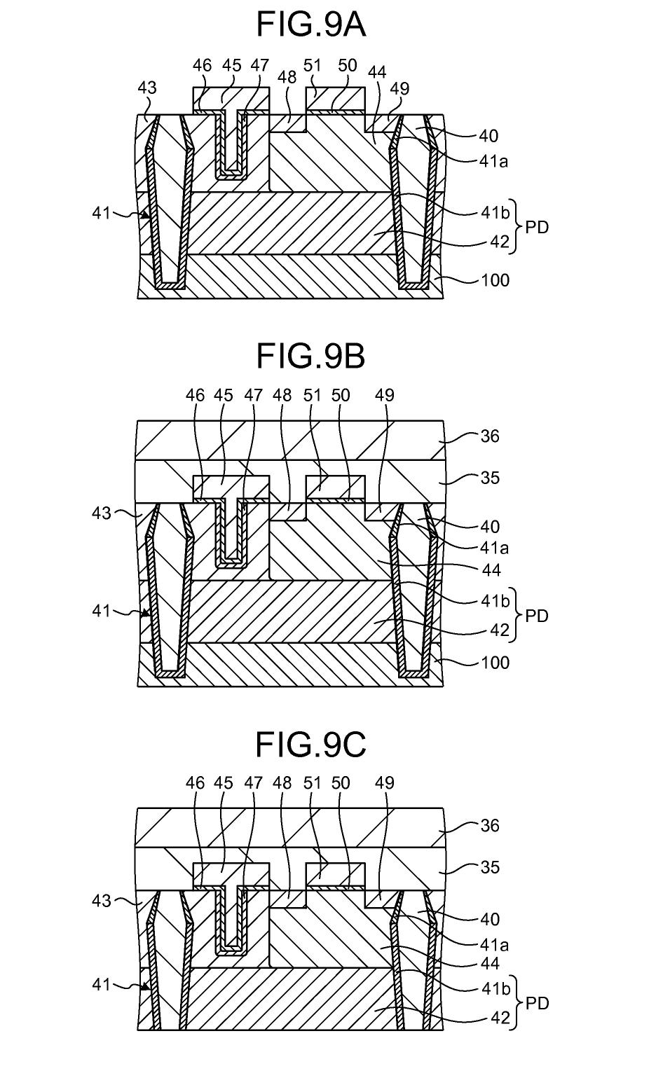

Subsequently, as illustrated in FIG. 9A, the buried gate 45 of the transfer transistor, the floating diffusion 48, the drain 49 of the reset transistor, and the reset gate 51 are formed on the surface layer of the epitaxial layer 43.

Here, first, a trench is formed at a position for forming the buried gate 45 on the surface layer of the epitaxial layer 43. Ions of a P-type impurity such as boron are implanted into the trench, and the annealing treatment is performed. The P-type semiconductor region 47 is thereby formed in the side surface of the trench.

Subsequently, a silicon oxide film is formed on an inner peripheral surface of the trench where the P-type semiconductor region 47 is formed and on the surface of the epitaxial layer 43 including the surface of the P-type well 44, and then a polysilicon layer is stacked thereon.

Thereafter, the polysilicon layer and the silicon oxide film are subjected to patterning. Unnecessary portions of the polysilicon and the silicon oxide film are removed from the surface of the epitaxial layer 43 including the surface of the P-type well 44. The buried gate 45, the reset gate 51, and the gate insulating films 46 and 50 are thereby formed.

Thereafter, ions of a N-type impurity such as phosphorus are implanted into both sides of the reset gate 51 on the surface layer of the P-type well 44, and the annealing treatment is performed. The floating diffusion 48 and the drain 49 of the reset transistor are thereby formed.

Subsequently, as illustrated in FIG. 9B, for example, tetraethoxysilane (TEOS) is stacked on the epitaxial layer 43 including the surface of the P-type well 44 to form the insulating layer 35, and the supporting substrate 36 is stacked on the insulating layer 35. The supporting substrate 36 is, for example, silicon wafer.

Subsequently, the supporting substrate 36 is supported, and the rear surface side of the semiconductor substrate 100 is ground and polished by chemical mechanical polishing (CMP). As illustrated in FIG. 9C, the rear surface of the N-type semiconductor region 42 as a light receiving surface of the photoelectric conversion elements PD is thereby exposed. Finally, the antireflection film 33, the color filter 32, and the microlens 31 are sequentially formed on the rear surface side of the N-type semiconductor region 42 to complete the pixel array 23 illustrated in FIG. 3.

As described above, the solid-state imaging device according to the first embodiment includes the FDTI isolating the photoelectric conversion elements from each other and the impurity diffusion layer arranged in the side surface of the FDTI. The FDTI includes a trench having a width enlarged from the surface of the semiconductor layer toward a position at a predetermined depth, and not enlarged at a position deeper than the position at the predetermined depth.

The impurity diffusion layer is arranged in the side surface of the trench. The impurity concentration in a portion from the surface of the semiconductor layer up to the position at the predetermined depth is lower than that in a portion deeper than the position at the predetermined depth. In this way, in the solid-state imaging device according to the first embodiment, by reducing the number of the ion implantation of the impurity for forming the impurity diffusion layer, a manufacturing process can be simplified.

### Second Embodiment

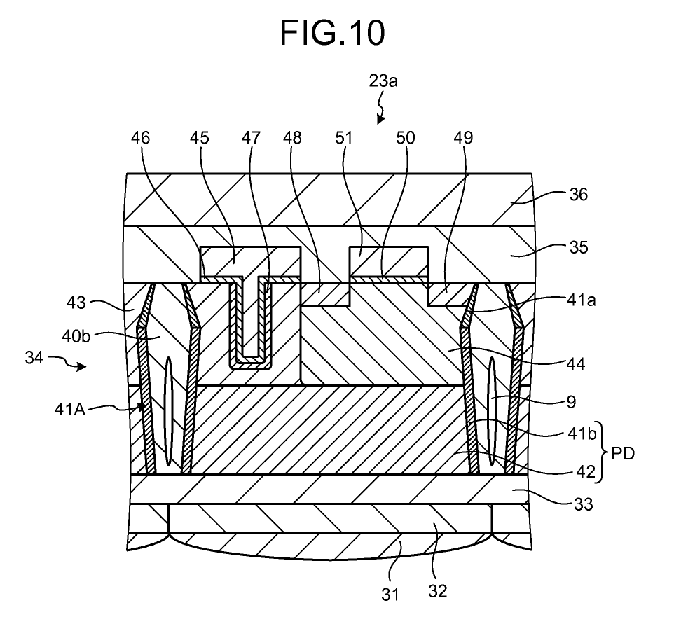

Next, a solid-state imaging device according to a second embodiment will be described with reference to FIG. 10. The solid-state imaging device according to the second embodiment has a similar structure to the solid-state imaging device 14 according to the first embodiment except that a structure of FDTI in a pixel array is different from each other. Therefore, here, a pixel array 23a according to the second embodiment will be described.

FIG. 10 is a view illustrating a schematic cross section of the pixel array 23a according to the second embodiment. Here, the same signs as those illustrated in FIG. 3 are given to the same components as those illustrated in FIG. 3 among the components illustrated in FIG. 10, and description thereof will be omitted.

As illustrated in FIG. 10, the pixel array 23a is different from the pixel array 23 illustrated in FIG. 3 in that an insulating portion 40b arranged in a trench of an FDTI 41A includes a slit-shaped void 9 extending in a depth direction of the trench of the FDTI 41A.

Therefore, in the pixel array 23a, light incident on the photoelectric conversion elements PD from an oblique direction is easily and totally reflected on an interface between the insulating portion 40b and the void 9 because of a difference in refractive index between silicon oxide as a material of the insulating portion 40b and air in the void 9. In such a case that the light incident on one of the photoelectric conversion elements PD from the oblique direction enters an adjacent one of photoelectric conversion elements PD, the optical color mixture is caused. In contrast, in the pixel array 23a having a structure capable of reflecting the incident light between the adjacent photoelectric conversion elements PD, optical color mixture can be suppressed.

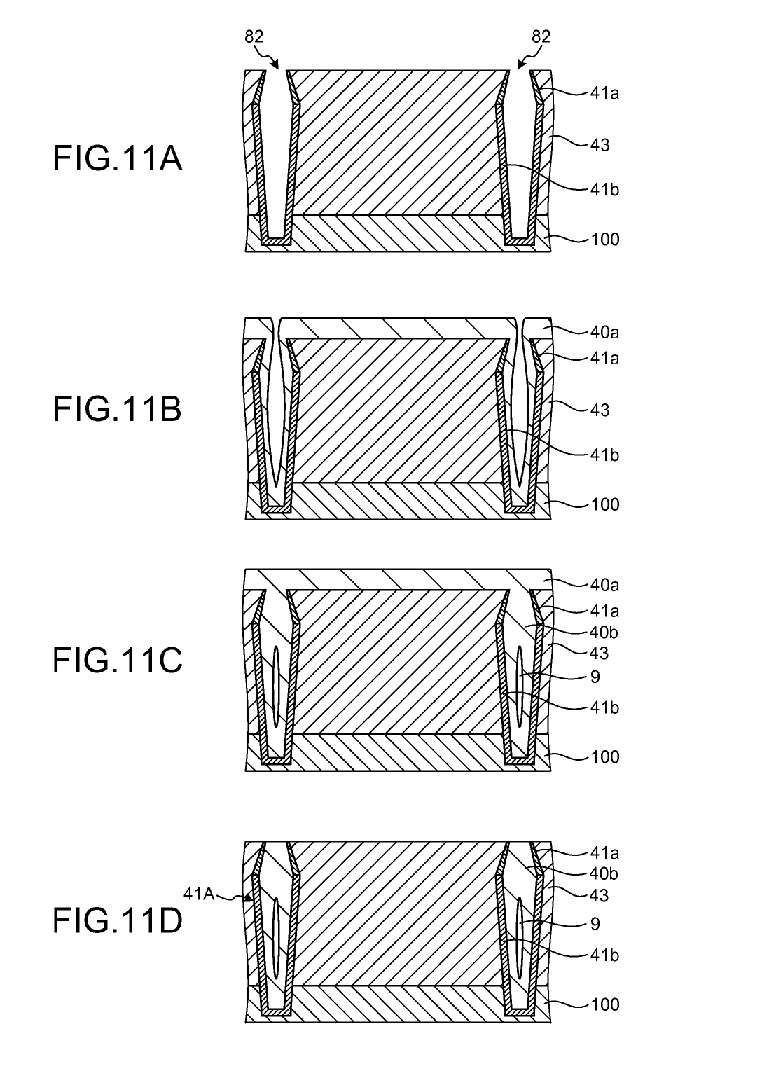

Next, a method for manufacturing the pixel array 23a will be described. FIGS. 11A to 11D are views illustrating a process for manufacturing the pixel array 23a according to the second embodiment. When the pixel array 23a is manufactured, a trench for the FDTI 41A is formed in a substrate in which an epitaxial layer 43 is formed on a semiconductor substrate 100 by approximately the same manufacturing process as the process illustrated in FIGS. 7A to 7D.

That is, the trench is formed so as to have a width enlarged in a linearly tapered shape from the surface of the epitaxial layer 43 toward a position at a predetermined depth, and reduced in a linearly tapered shape from the position at the predetermined depth toward the rear surface of the epitaxial layer 43. However, the trench for the FDTI 41A is different from that in the first embodiment in that the width of the trench for the FDTI 41A on the surface of the epitaxial layer 43 is smaller than that in the first embodiment.

Subsequently, as in the first embodiment, ions of a P-type impurity are implanted once into each side surface of the trench for the FDTI 41A from an oblique direction, and an annealing treatment is performed. In this way, as illustrated in FIG. 11A, a low concentration P-type region 41a and a high concentration P-type region 41b are formed simultaneously in a side surface of the trench 82.

Thereafter, as illustrated in FIG. 11B, a silicon oxide layer 40a is stacked on the surface of the epitaxial layer 43 by CVD. Thereafter, when stacking of the silicon oxide layer 40a is continued, as illustrated in FIG. 11C, an upper end of the trench 82 for the FDTI 41A is closed before the trench 82 is filled with silicon oxide because the upper end of the trench 82 is narrow. The slit-shaped void 9 is formed in the insulating portion 40b.

Subsequently, as illustrated in FIG. 11D, the unnecessary silicon oxide layer 40a is removed from the surface of the epitaxial layer 43. Thereafter, as in the first embodiment, the process illustrated in FIG. 8D and the succeeding processes are performed to complete the pixel array 23a. In this way, according to the second embodiment, only by making the width of the upper end of the trench 82 for the FDTI 41A smaller, it is possible to manufacture the pixel array 23a having high ability to suppress optical color mixture.

As described above, the solid-state imaging device according to the second embodiment includes the slit-shaped void extending in the depth direction of the trench in the FDTI at the depth position of the N-type semiconductor region as a charge storage region of the photoelectric conversion elements. As a result, the solid-state imaging device according to the second embodiment can suppress optical color mixture because of a difference in refractive index between the FDTI and the slit-shaped void.

### Third Embodiment

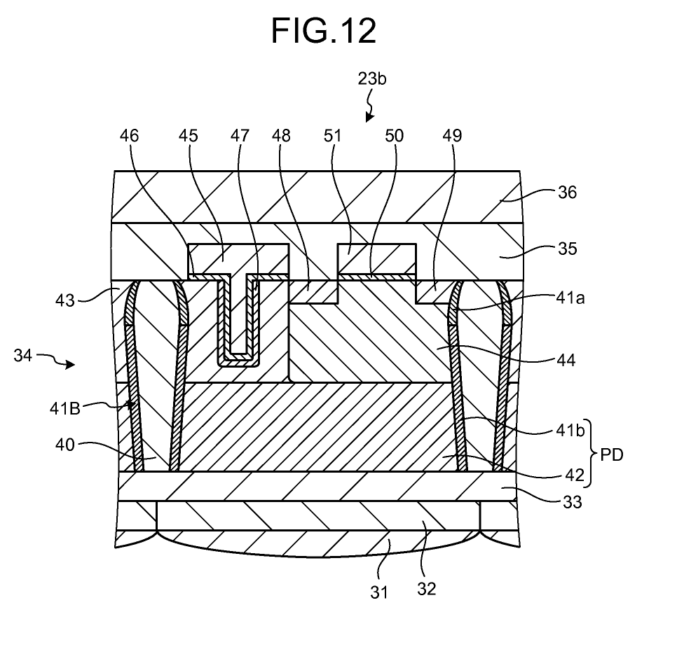

Next, a solid-state imaging device according to a third embodiment will be described with reference to FIG. 12. The solid-state imaging device according to the third embodiment has a similar structure to the solid-state imaging device 14 according to the first embodiment except that a structure of FDTI in a pixel array is different from each other. Therefore, here, a pixel array 23b according to the third embodiment will be described.

FIG. 12 is a view illustrating a schematic cross section of the pixel array 23b according to the third embodiment. Here, the same signs as those illustrated in FIG. 3 are given to the same components as those illustrated in FIG. 3 among the components illustrated in FIG. 12, and description thereof will be omitted.

As illustrated in FIG. 12, the pixel array 23b according to the third embodiment is different from the pixel array illustrated in FIG. 3 in that a portion of a trench of an FDTI 41B from the surface of an epitaxial layer 43 up to a position at a predetermined depth has a parabola-tapered shape.

The trench for the FDTI 41B of the pixel array 23b is formed in a parabola-tapered shape by performing etching once on both side surfaces of an upper portion thereof. That is, according to the third embodiment, by performing etching once, the trench for the FDTI 41B can be formed into a shape having a width reduced in the parabola-tapered shape from the position at the predetermined depth in the epitaxial layer 43 toward the surface.

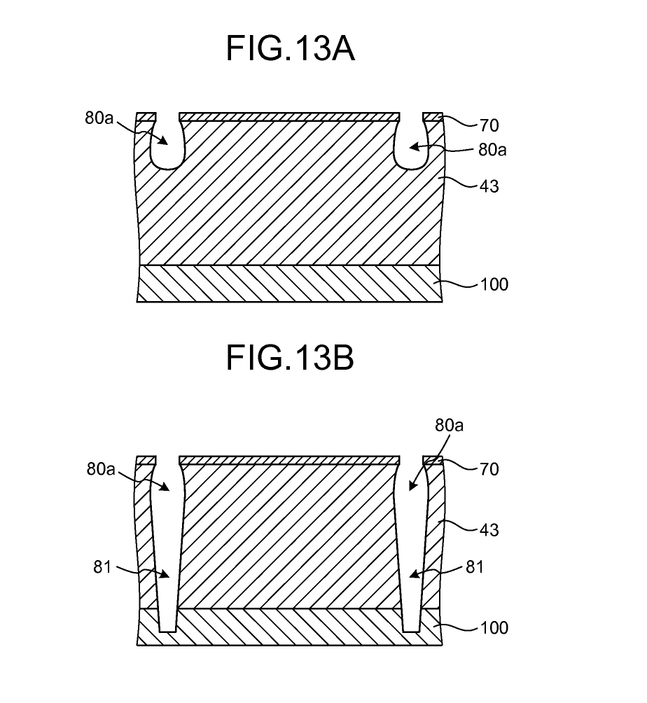

FIGS. 13A and 13B are cross sectional views illustrating a process for manufacturing the pixel array 23b according to the third embodiment. Note that FIGS. 13A and 13B illustrate a process for forming the trench for the FDTI 41B according to the third embodiment. As illustrated in FIG. 13A, when the trench for the FDTI 41B according to the third embodiment is formed, first, a hard mask 70 in which a position for forming the trench is selectively removed is formed on the epitaxial layer 43.

Then, the hard mask 70 is used as a mask, and dry or wet isotropic etching is performed to the epitaxial layer 43. A first trench 80a is thereby eroded in a section-view barrel shape. The first trench 80a having a width reduced in the parabola-tapered shape from the position at the predetermined depth in the epitaxial layer 43 toward the surface can be formed.

Subsequently, as illustrated in FIG. 13B, anisotropic etching is performed to the bottom surface of the first trench 80a in a thickness direction of the epitaxial layer 43 to thereby form a second trench 81 continuous to the first trench 80a. The second trench 81 has a similar shape to the second trench 81 illustrated in FIG. 7D. Thereafter, as in the pixel array 23 according to the first embodiment, the manufacturing processes illustrated in FIGS. 8A to 8D and the succeeding processes are performed to complete the pixel array 23b illustrated in FIG. 12.

As described above, the pixel array 23b according to the third embodiment has the parabola-tapered shape in a portion of the trench of the FDTI 41B from the surface of the epitaxial layer 43 up to the position at the predetermined depth.

Therefore, according to the third embodiment, by performing etching once, the trench for the FDTI 41B can be formed into the shape having a width reduced in the parabola-tapered shape from the position at the predetermined depth in the epitaxial layer 43 toward the surface, and a manufacturing process can be further simplified.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A solid-state imaging device comprising:
a plurality of photoelectric conversion elements two-dimensionally arranged in a semiconductor layer;
a field effect transistor including N-type source and drain on a surface side of the semiconductor layer;
a trench penetrating through a surface and a rear surface of the semiconductor layer and surrounding each of the photoelectric conversion elements, a width of the trench being enlarged from the surface of the semiconductor layer toward a position at a predetermined depth, and not being enlarged at a position deeper than the position at the predetermined depth; and
a P-type impurity diffusion region arranged in a side surface of the trench, a P-type impurity concentration in a portion from the surface of the semiconductor layer to the position at the predetermined depth being lower than that in a portion deeper than the position at the predetermined depth.

2. The solid-state imaging device according to claim 1, wherein
the width of the trench is reduced in a linearly tapered shape from the position at the predetermined depth in the semiconductor layer toward the surface.

3. The solid-state imaging device according to claim 2, wherein
a tapered angle of the trench at a portion in which the width is reduced in a linearly tapered shape with respect to the surface of the semiconductor layer is 85.7° or less.

4. The solid-state imaging device according to claim 1, wherein
the width of the trench is approximately constant or reduced in a tapered shape from the position at the predetermined depth toward the rear surface of the semiconductor layer.

5. The solid-state imaging device according to claim 4, wherein
a tapered angle of the trench at a portion in which the width is approximately constant or reduced in a tapered shape with respect to the rear surface of the semiconductor layer is 88° or more and 90° or less.

6. The solid-state imaging device according to claim 1, wherein
the position at the predetermined depth is deeper than the source and the drain of the field effect transistor in the semiconductor layer and shallower than a charge storage region of the photoelectric conversion elements.

7. The solid-state imaging device according to claim 1, wherein
in the P-type impurity diffusion region, the P-type impurity concentration in the portion from the surface of the semiconductor layer to the position at the predetermined depth is 2E17 [atoms/cm³] to 5E17 [atoms/cm³], and the P-type impurity concentration in the portion deeper than the position at the predetermined depth is 1E18 [atoms/cm³] or more.

8. The solid-state imaging device according to claim 1, further comprising an insulating portion in the trench, wherein
the insulating portion includes a slit-shaped void extending in a depth direction of the trench.

9. The solid-state imaging device according to claim 8, wherein
the void is arranged at a depth position where a charge storage region of the photoelectric conversion elements is arranged in the semiconductor layer.

10. The solid-state imaging device according to claim 1, wherein
the width of the trench is reduced in a parabola-tapered shape from the position at the predetermined depth in the semiconductor layer toward the surface.

11. A method for manufacturing a solid-state imaging device, comprising:
forming a trench dividing a semiconductor layer into lattice shaped parts, a width of the trench being enlarged from a surface of the semiconductor layer toward a position at a predetermined depth, and not being enlarged at a position deeper than the position at the predetermined depth;
implanting ions of a P-type impurity into a side surface of the trench at a predetermined tilt angle and performing an annealing treatment;
forming an N-type impurity diffusion region for forming photoelectric conversion elements at a position deeper than a surface layer in the semiconductor layer; and
forming N-type source and drain of a field effect transistor on the surface layer in the semiconductor layer divided by the trench.

12. The method for manufacturing a solid-state imaging device according to claim 11, wherein:
the forming the trench includes:
performing anisotropic etching to a position for forming the trench on the surface of the semiconductor layer in an oblique direction to form a first trench, the width of the first trench being enlarged from the surface of the semiconductor layer toward the position at the predetermined depth; and
performing anisotropic etching to a bottom surface of the first trench in a depth direction of the semiconductor layer to form a second trench, the width of the second trench not being enlarged at the position deeper than the position at the predetermined depth in the semiconductor layer.

13. The method for manufacturing a solid-state imaging device according to claim 12, wherein:
the first trench is formed in such a manner that the width of the first trench is reduced in a linearly tapered shape from the position at the predetermined depth in the semiconductor layer toward the surface.

14. The method for manufacturing a solid-state imaging device according to claim 13, wherein
a tapered angle of the first trench with respect to the surface of the semiconductor layer is 85.7° or less.

15. The method for manufacturing a solid-state imaging device according to claim 12, wherein:
the second trench is formed in such a manner that the width of the second trench is approximately constant or reduced in a linearly tapered shape from the position at the predetermined depth toward a rear surface of the semiconductor layer.

16. The method for manufacturing a solid-state imaging device according to claim 15, wherein
a tapered angle of the second trench with respect to the rear surface of the semiconductor layer is 88° or more and 90° or less.

17. The method for manufacturing a solid-state imaging device according to claim 12, wherein:
the first trench is formed in such a manner that the position at the predetermined depth is deeper than a depth where the source and the drain of the field effect transistor in the semiconductor layer are to be formed and shallower than a depth where a charge storage region of the photoelectric conversion elements is to be formed.

18. The method for manufacturing a solid-state imaging device according to claim 11, further comprising
forming, in the trench, an insulating portion including a slit-shaped void extending in a depth direction of the trench.

19. The method for manufacturing a solid-state imaging device according to claim 18, wherein
the N-type impurity diffusion region is formed at a depth position where the void is formed in the semiconductor layer.

20. The method for manufacturing a solid-state imaging device according to claim 11, wherein:
the forming the trench includes:
performing isotropic etching to a position for forming the trench on the surface of the semiconductor layer to form a first trench, the width of the first trench being enlarged from the surface of the semiconductor layer toward the position at the predetermined depth; and
performing anisotropic etching to a bottom surface of the first trench in a depth direction of the semiconductor layer to form a second trench, the width of the second trench not being enlarged at the position deeper than the position at the predetermined depth in the semiconductor layer.
